(19) United States
(12) Patent Application Publication
(10) Pub. No.: US 2009/0011158 A1
(43) Pub. Date: Jan. 8, 2009

(54) MICRONEEDLE STRUCTURES AND CORRESPONDING PRODUCTION METHODS EMPLOYING A BACKSIDE WET ETCH

(75) Inventor: YEHOSHUA YESHURUN, Haifa (IL)

Correspondence Address: DR. MARK M. FRIEDMAN;C/O BILL POLKINGHORN - DISCOVERY DISPATCH, 9003 FLORIN WAY, UPPER MARLBORO, MD, 20772, US

(73) Assignee: NanoPass Technologies Ltd., Nes Ziona (IL)

(21) Appl. No.: 12/050,209

(22) Filed: Mar. 18, 2008

Related U.S. Application Data
(60) Provisional application No. 60/895,467, filed on Mar. 18, 2007.

(51) Int. Cl. B29D 22/00; H01L 21/00

(52) U.S. Cl. 428/34.1; 438/51

(57) ABSTRACT

A method for forming a hollow microneedle structure includes processing the front side of a wafer to form at least one microneedle projecting from a substrate with a first part of a through-bore, formed by a dry etching process, passing through the microneedle and through a part of a thickness of the substrate. The backside of the wafer is also processed to form a second part of the through-bore by a wet etching process.

### FIELD AND BACKGROUND OF THE INVENTION

The present invention relates to microneedle structures and corresponding production methods and, in particular, it concerns hollow microneedle structures in which a through-bore is formed partially by a dry etching process and partially by a wet etching process.

In MEMS technology, several processing techniques are available for use in fabricating devices, each with its own particular characteristics, advantages and disadvantages. Of particular importance in the context of the present invention are two groups of processing techniques referred to generically as “wet etching processes” and “dry etching processes.” In the dry etching processes category, particular reference will be made to Deep Reactive Ion Etching (DRIE).

In wet etching processes, a wafer with a suitable mask is processed by immersion in an etchant so as to selectively etch away parts of the wafer to form a desired structure. The etching process may be isotropic, i.e., occurring at a constant rate in all directions allowed by the mask, independent of the crystallographic planes of the wafer, or may be anisotropic, i.e., eroding material along specific crystallographic planes. Examples of anisotropic etching processes (such as KOH in silicon on (100) and (110) planes respectively) are illustrated in FIGS. 1A and 1B, while examples of isotropic etching processes (such as HF, Nitric Acid or Acetic Acid in silicon) are illustrated in FIGS. 1C and 1D. Wet etching techniques are advantageous for being rapid, low cost, and allowing parallel processing of multiple wafers. Wet etching techniques are however limited as to what structures they can produce and, most notably, cannot be used for forming high aspect ratio structures, i.e., a height or depth of the structure are large compared to the width, or where near-vertical surfaces are required.

In order to manufacture a high aspect ratio structure or hole, DRIE techniques are used. For example, in the field of hollow microneedles, a hole with a high aspect ratio hole (greater then 10:1) is often required. Such holes cannot be formed using conventional wet etching techniques, so a DRIE technique is used instead.

DRIE is typically implemented either using a process known as “the BOSCH® process” (including repeated deposition of a passivation layer) or under cryogenic conditions, thereby inhibiting isotropic etching and limiting the etching process to the direction of direct ion bombardment. This process can form structures perpendicular to a wafer surface, for example a silicon wafer, with high aspect ratio such as holes and wall structures with substantially any desired cross sectional shape.

DRIE processing is a batch process, typically only allowing processing of one wafer at a time, and with limitations on the wafer size. Furthermore, the process itself is relatively slow, optimally performed at a rate of roughly 10 microns per minute, and requires relatively large and expensive equipment. As a result, a DRIE production step is often the limiting factor in rates of production of a MEMS system, and accounts for a relatively large proportion of the production costs.

For these reasons, where possible, it is advantageous to employ wet etching processes in which relatively low costs chemical materials are used to create structure and channels in silicon, and multiple wafers can be etched simultaneously.

In the field of microneedle fabrication, U.S. Pat. No. 6,533,949 to Yeshurun et al. (hereafter “the '949 patent”), which is hereby incorporated by reference in its entirety, discloses fabrication techniques for hollow microneedles in which DRIE processes are used to form upright surfaces of the microneedles and a through-bore while wet etching techniques are used to form an oblique surface, thereby defining various hollow microneedle structures. The structures described therein have been found highly advantageous, combining robustness and sharpness, as well as providing a geometry for a fluid flow bore which does not become blocked during penetration of the skin. The production technique described, however, relies upon dry etching to form the full length of the fluid flow bore passing through the substrate, with the consequent implications for the production processing efficiency and costs.

It would therefore be highly advantageous to provide a structure and corresponding production method which would maintain the advantageous properties of the structures taught by the '949 patent and variants or modifications thereof while employing wet etching techniques to replace at least some of the dry etching steps previously described.

### SUMMARY OF THE INVENTION

The present invention is a method for forming a hollow microneedle structure and a corresponding microneedle structure.

According to the teachings of the present invention there is provided, a method for forming a hollow microneedle structure comprising the steps of: (a) providing a wafer having a front side and a backside; (b) processing the front side to form at least one microneedle projecting from a substrate and a first part of a through-bore passing through the microneedle and through a part of a thickness of the substrate; and (c) processing the backside to form a second part of the through-bore, wherein the first part of the through-bore is formed by a dry etching process, and wherein the second part of the through-bore is formed by a wet etching process.

According to a further feature of the present invention, the wafer is a silicon wafer.

According to a further feature of the present invention, the second part of the through-bore is formed by an isotropic wet etching process.

According to a further feature of the present invention, the second part of the through-bore is formed by an anisotropic wet etching process.

According to a further feature of the present invention, the first part of the through-bore has an aspect ratio greater than 10:1.

According to a further feature of the present invention, the first part of the through-bore is formed by deep reactive ion etching.

According to a further feature of the present invention, an external shape of the microneedle is formed by at least two intersecting surfaces, at least a first of the surfaces being formed by a dry etching process and at least a second of the surfaces being formed by a wet etching process.

According to a further feature of the present invention, the first surface and the first part of the through-bore are formed concurrently.

According to a further feature of the present invention, the second surface and the second part of the through-bore are formed concurrently.

According to a further feature of the present invention, the second part of the through-bore is formed prior to the first part of the through-bore, and wherein the second surface is formed subsequent to the first part of the through bore.

According to a further feature of the present invention, the first part of the through-bore intersects the second surface.

According to a further feature of the present invention, the backside is further processed by a supplementary dry etch process to form a third part of the through-bore within the second part, the third part intersecting the first part to form the through-bore.

According to a further feature of the present invention, a plurality of the microneedles with the through-bores are formed in distinct regions of the wafer for subdivision into chips, and the method further comprises forming, by a wet etching process, dicing channels on at least one of the backside and the front side extending along dicing lines between the distinct regions.

According to a further feature of the present invention, the dicing channels are formed concurrently with the second parts of the through-bores.

According to a further feature of the present invention, the dicing channels are formed on both the front side and the backside.

According to a further feature of the present invention, the dicing channels are formed so as to traverse an entire thickness of the substrate, thereby separating the distinct regions into chips.

According to a further feature of the present invention, a dicing process is performed to sever a remaining thickness of the wafer after formation of the dicing channels so as to separate the distinct regions into chips.

According to a further feature of the present invention, a plurality of the microneedles with the through-bores are formed in distinct regions of the wafer for subdivision along dicing lines into chips, and wherein the method further comprises forming, by a wet etching process, a trench on the backside, the trench substantially circumscribing the through-bore of each distinct region and spaced inwardly from the dicing lines.

According to a further feature of the present invention, at least one trench extension contiguous with the trench and extending to one of the dicing lines is formed on the backside by a wet etching process.

According to a further feature of the present invention, a plurality of non-contiguous recessed features are formed on the backside outside the trench by a wet etching process so as to enhance an available contact surface for receiving an adhesive.

According to a further feature of the present invention: (a) the distinct regions are separated along the dicing lines so as to form chips; (b) adhesive is applied to a peripheral area of the backside of one of the chips outside the trench; and (c) the chip is adhered to a support structure to form a microneedle device, such that any excess adhesive collects within the trench, thereby avoiding clogging of the through-bore.

According to a further feature of the present invention, a plurality of the microneedles with the through-bores are formed in distinct regions of the wafer for subdivision along dicing lines into chips, and the method further comprises forming, by a wet etching process, a plurality of non-contiguous recessed features on the backside so as to enhance an available contact surface for receiving an adhesive.

There is also provided according to the teachings of the present invention, a hollow microneedle structure comprising: (a) a substrate having a front side and a backside; (b) at least one microneedle projecting from the front side of the substrate; and (c) a through-bore passing through the microneedle and through the substrate, wherein a first part of the through-bore extending from the microneedle through a first portion of a thickness of the substrate is formed by a dry etching process, and wherein a second part of the through-bore extending from the backside through a second portion of the thickness of the substrate is formed by a wet etching process.

According to a further feature of the present invention, the substrate and the microneedle are formed from silicon.

According to a further feature of the present invention, the second part of the through-bore is formed by an isotropic wet etching process.

According to a further feature of the present invention, the second part of the through-bore is formed by an anisotropic wet etching process.

According to a further feature of the present invention, the first part of the through-bore has an aspect ratio greater than 10:1.

According to a further feature of the present invention, an external shape of the microneedle is formed by at least two intersecting surfaces, at least a first of the surfaces being an upright surface relative to the front side and at least a second of the surfaces being an oblique surface relative to the front side.

According to a further feature of the present invention, the first part of the through-bore intersects the oblique surface.

According to a further feature of the present invention, the substrate has a boundary, and wherein the backside features a trench substantially circumscribing the through-bore and spaced inwardly from the boundary.

According to a further feature of the present invention, the backside further includes at least one trench extension formed by a wet etching process, the trench extension being contiguous with the trench and extending the boundary.

According to a further feature of the present invention, there is also provided: (a) a support structure for supporting the substrate; and (b) a layer of adhesive applied to a peripheral area of the backside outside the trench, the layer of adhesive attaching the substrate to the support structure.

According to a further feature of the present invention, the backside further includes a plurality of non-contiguous recessed features formed by a wet etching process so as to enhance an available contact surface for receiving an adhesive.

There is also provided according to the teachings of the present invention, a method for forming a hollow microneedle structure comprising the steps of: (a) providing a wafer having a front side and a backside; (b) processing the front side to form: (i) a plurality of microneedles projecting from a substrate in distinct regions of the wafer for subdivision along dicing lines into chips, and (ii) a first part of a through-bore passing through each of the microneedles and through a part of a thickness of the substrate; and (c) processing the backside to form: (i) a second part of the through-bore for each microneedle, and (ii) a trench substantially circumscribing the through-bore of each distinct region and spaced inwardly from the dicing lines.

There is also provided according to the teachings of the present invention, a method for forming a hollow microneedle structure comprising the steps of: (a) providing a wafer having a front side and a backside; (b) processing the front side to form: (i) a plurality of microneedles projecting from a substrate in distinct regions of the wafer for subdivision along dicing lines into chips, and (ii) a first part of a through-bore passing through each of the microneedles and through a part of a thickness of the substrate; and (c) processing the backside to form: (i) a second part of the through-bore for each microneedle, and (ii) a plurality of non-contiguous recessed features so as to enhance an available contact surface for receiving an adhesive.

There is also provided according to the teachings of the present invention, a method for forming a hollow microneedle structure comprising the steps of: (a) providing a wafer having a front side and a backside; (b) processing the front side to form: (i) a plurality of microneedles projecting from a substrate in distinct regions of the wafer for subdivision along dicing lines into chips, and (ii) at least part of a through-bore passing through each of the microneedles and a thickness of the substrate; and (c) forming, by a wet etching process, dicing channels on at least one of the backside and the front side extending along dicing lines between the distinct regions.

### BRIEF DESCRIPTION OF THE DRAWINGS

The invention is herein described, by way of example only, with reference to the accompanying drawings, wherein:

FIGS. 1A-1D, described above, are schematic illustrations of the results of various known anisotropic and isotropic etching processes;

FIGS. 2A-2G are schematic cross-sectional views illustrating stages during a method for forming a hollow microneedle structure according to the teachings of the present invention;

FIGS. 3A and 3B are partially cut-away isometric views of a first implementation of a microneedle structure, constructed and operative according to the teachings of the present invention, produced by the method of FIGS. 2A-2G;

FIGS. 3C and 3D are partially cut-away isometric views of a second implementation of a microneedle structure, constructed and operative according to the teachings of the present invention, produced by the method of FIGS. 2A-2G;

FIG. 4 is a schematic isometric view illustrating a dicing process including one or more wet etched dicing channels according to a further aspect of the present invention;

FIG. 5 is a schematic isometric view illustrating a glue-control trench pattern according to a still further aspect of the present invention; and

FIG. 6 is a schematic isometric view illustrating an adhesion enhancement pattern according to a yet further aspect of the present invention.

### DESCRIPTION OF THE PREFERRED EMBODIMENTS

The present invention is a method for forming a hollow microneedle structure and correspond microneedle structures.

The principles and operation of production methods and structures according to the present invention may be better understood with reference to the drawings and the accompanying description.

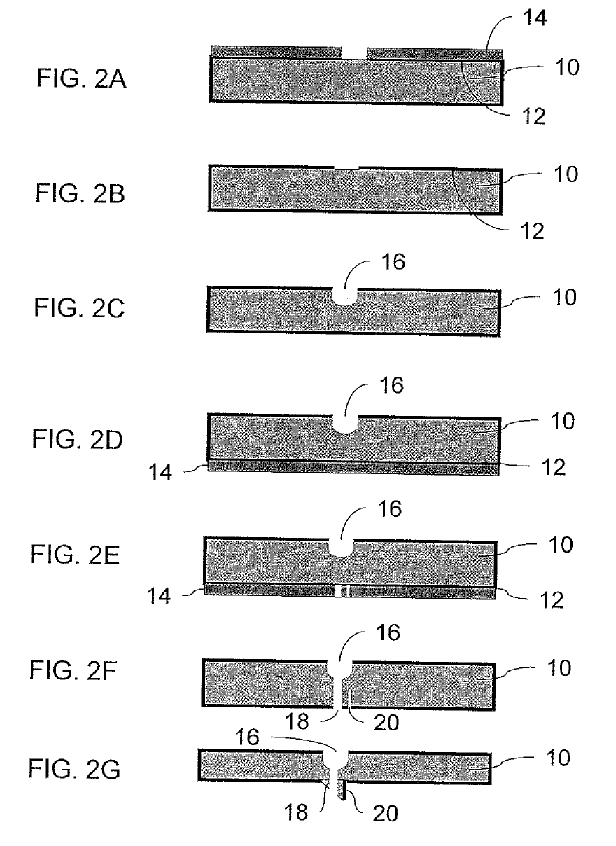

Referring now to the drawings, FIGS. 2A-2G illustrate schematically stages during fabrication of a microneedle structure according to an implementation of the method of the present invention. Generally speaking, a method for forming a hollow microneedle structure according to the present invention starts with providing a wafer, generally designated 10, which is preferably but not necessarily a single crystal silicon wafer. The side on which the microneedles are to be fabricated is referred to as the front side of the wafer, and the reverse side is referred to as the backside of the wafer. In the illustrations of FIGS. 2A-2G, the wafer is shown with backside upwards.

The processing of the wafer includes processing the front side to form at least one microneedle projecting from a substrate and a first part of a through-bore passing through the microneedle and through a part of a thickness of the substrate. The processing of the wafer also includes processing the backside to form a second part of the through-bore, the first part and the second part intersecting or being joined by a third part to form the through-bore. It is a feature of certain particularly preferred implementations of the present invention that the first part of the through-bore is formed by a dry etching process, and the second part of the through-bore is formed by a wet etching process. In this manner, the production time and costs are significantly reduced relative to the technique of the aforementioned U.S. Pat. No. 6,533,949 which forms the entirety of the through bore for each microneedle by DRIE techniques. This and other advantages of the present invention will become clearer from the following description.

Before addressing the features of the present invention in more detail, it will be helpful to define certain terminology as used herein in the description and claims. The term “MEMS” is used herein loosely to refer to the field of technology and corresponding production techniques for producing mechanical structures with dimensions in the micron range up to several hundred microns. In most cases, the microneedle structures of the present invention do not include electronic components and could thus be more accurately referred to as “MMS”.

The term “wafer” is used to refer to a block of material from which the microneedle structures of the present invention are produced, primarily by etching techniques. The invention applies primarily to semiconductor wafers, and most preferably to silicon wafers. It should be noted that the structures of the present invention may be referred to as “formed from silicon” despite a surface layer of silicon dioxide which is always present under ambient conditions, and which may be further developed in order to impart desired mechanical or other properties to the final structure, all as is well known in the art.

The term “etching” is used to refer to any process step which selectively removes material from the wafer. “Wet etching” is used to refer to processes in which surfaces of the wafer are selectively covered by a mask and the wafer is then exposed in its entirety, or at least over an entire side, to a chemical etchant, whether by immersion in a bath, by spray application or by any other type of exposure. “Dry etching” is used to refer to processes in which an active species effective to cause etching is applied directionally to the wafer surface, as exemplified by reactive ion etching (RIE). The term “deep reactive ion etching” (DRIE) is used generically to refer to any implementation of RIE or a similar process which is effective to form high aspect ratio features and/or near vertical surfaces. Examples of DRIE include, but are not limited to, cryogenic-DRIE and BOSCH©-process DRIE. Practical implementation details for all of the various etching techniques referred to herein are, per se, well known to those ordinarily skilled in the art, and will not be addressed here in detail.

The term “substrate” is used to refer to the remaining thickness of the substrate which provides an underlying roughly planar surface from which the final microneedles project. Commonly, a single wafer may be processed to fabricate a plurality of microneedle structures at the same time. In such cases, the term “chip” refers to a defined sub-region of the wafer (or substrate) which is to be severed or otherwise separated along “dicing lines” to form a microneedle structure. Unless otherwise specified, the term “dicing” refers to any technique which can be employed to separate a wafer into chips along dicing lines. The term “sever” is used to refer specifically to a cutting operation performed by a saw or other mechanical cutting device.

The term “microneedle” is used herein to refer to a solid structure protruding from a substrate to a height of between 30 microns and 1000 microns, and most preferably between 250 microns and 800 microns. A microneedle is referred to as “hollow” if it has a bore passing through it to allow supplying or sampling of fluid through the bore. The hole or bore is referred to as a “through-bore” if it passes through to the backside of the substrate. The bore can have any cross-sectional shape.

When reference is made to the “external shape” of the microneedle, this refers to the external surfaces making up the three dimensional shape of the microneedle without reference to the internal surfaces of the bore. Surfaces or directions are referred to as “upright” if they are generally perpendicular to the surface of the wafer or the substrate. For convenience of reference, use may be made of “vertical”, “up”, “down”, “height” or the like to refer to directions or dimensions generally perpendicular to the initial plane of the surface of the wafer, and “horizontal”, “width” or the like to refer to directions or dimensions generally parallel to the initial plane of the surface of the wafer. The work “oblique” is used to refer to a surface which is significantly inclined both to the horizontal and vertical, and typically forming an angle of between 20 degrees and 70 degrees to the upright.

The term “aspect ratio” refers to the ratio of the height to width of a given structure or feature. Particularly in relation to a roughly parallel sided bore, the aspect ratio corresponds to the ratio of the depth of the parallel-sided portion of the bore to the diameter (or otherwise defined maximum width) of the bore.

Channels, trenches or recesses etched into a surface are referred to as “contiguous” if fluid can pass from one to the other without rising above the level of the surrounding surfaces. Conversely, recesses are “non-contiguous” if fluid cannot pass between them without rising above the level of the surrounding surfaces.

The term “concurrently” refers to two operations which occur during coincident or overlapping time periods, either where one begins and ends during the duration of the other, or where a later one starts before the completion of the other. The term “subsequently” refers to a later operation which occurs after completion of the earlier operation. It should be noted that any reference in the description and claims to a plurality of operations or steps should not be taken to define any particular order in which the operations or steps are to be performed unless such temporal relation is explicitly stated.

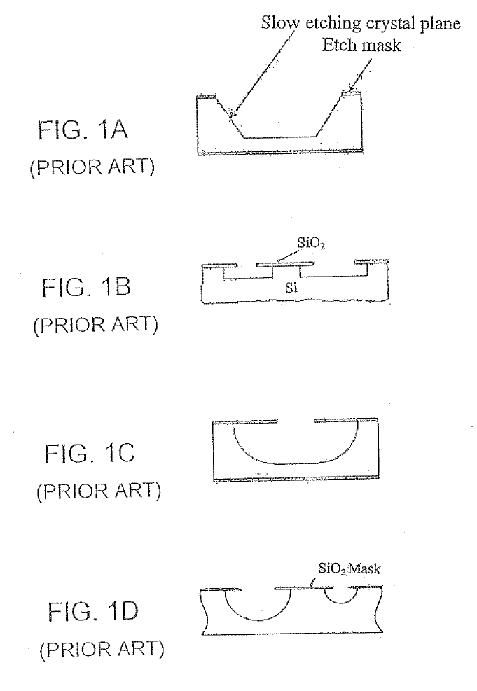

Turning now to the features of the present invention in more detail, FIGS. 2A-2G illustrate one exemplary implementation of the method of the present invention in which the backside wet etch processing is performed prior to the front side processing. In this case, a silicon wafer 10 is coated with a passivation layer 12 such as silicon dioxide or silicon nitride, the backside is coated with a layer of photoresist 14, and the photoresist is irradiated through a mask (not shown) to define a pattern of elements to be etched. After irradiation, the unexposed portion of the photoresist (or in the case of negative photoresist, the exposed portion) is removed, and the selectively exposed portions of the passivation layer are chemically removed. This renders the state illustrated in FIG. 2A. The remaining photoresist is then chemically removed (FIG. 2B), and the backside wet etching process is then performed to give the form illustrated in FIG. 2C. In the schematic case illustrated here, the etched feature shown is a rear part 16 of a through-bore, as will become clear below. All of the steps described thus far are, in themselves, standard procedures performed during wet etch processing, and practical details for implementing them, as well as various variants and alternatives, will be clear to one ordinarily skilled in the art. The wet etching process itself may be an isotropic etching process or an anisotropic etching process, as defined above with reference to FIGS. 1A-1D. The differing results of these options will be discussed further below.

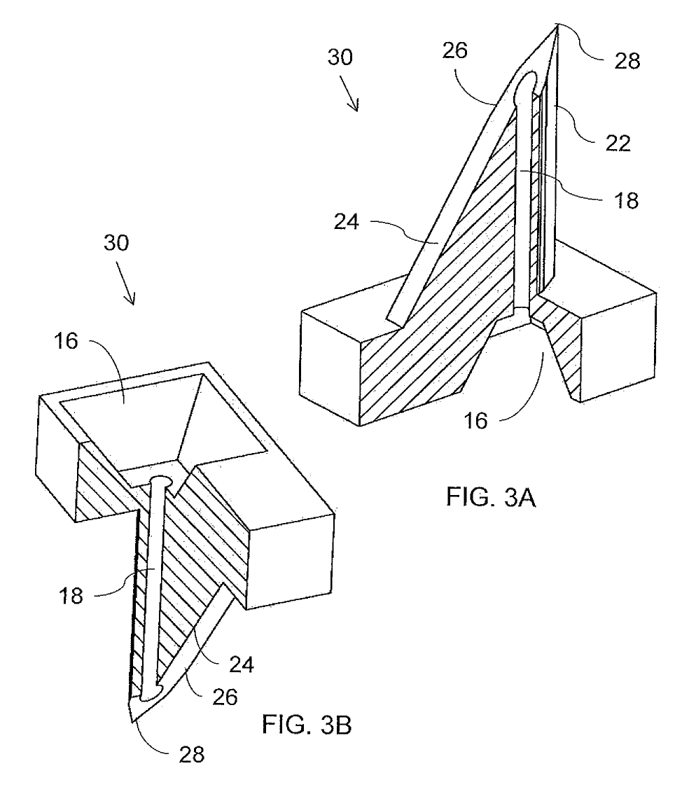

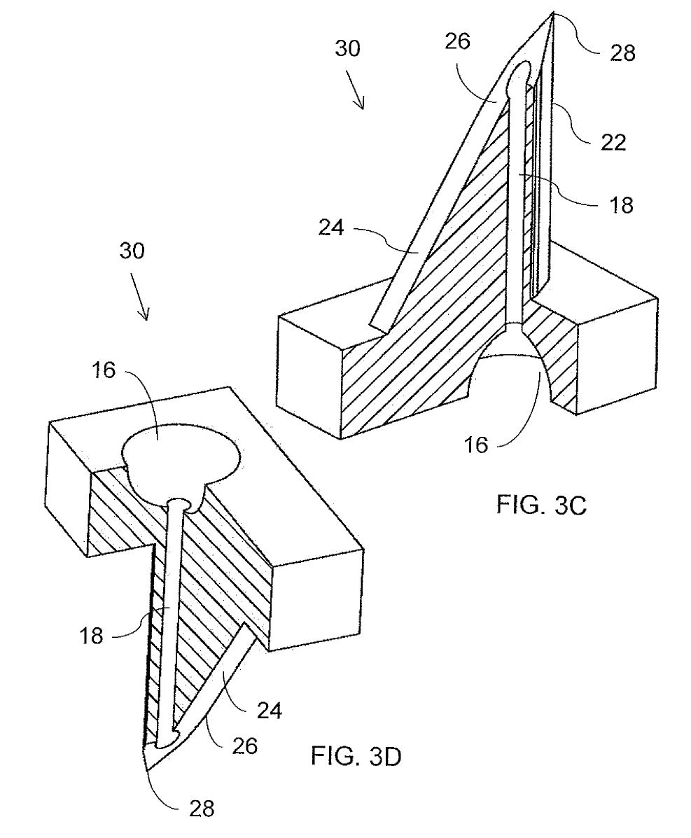

FIGS. 2D-2G describe schematically the front side processing employed to form a structure of robust microneedles with through-bores. The front side processing shown in this exemplary example is equivalent to that described in the aforementioned U.S. Pat. No. 6,533,949, particularly with reference to FIGS. 2A and 2C-2F thereof. Prior to front side processing, the backside surface and bore are preferably coated with a protective material to protect them from further erosion during the front side processing. The front side is coated with a passivation layer and a layer of photoresist (FIG. 2D) which is selectively exposed to define a pattern corresponding to a front part 18 of the through-bore partially encompassed by a narrow slot 20 for forming upright surfaces of the final microneedle (FIG. 2E). Front part 18 of the through bore has an aspect ratio in excess of 10:1, thereby requiring dry etching techniques as discussed above. After removal of the selectively exposed portions of the passivation layer, and the remainder of the photoresist, a dry etching process, particularly DRIE, is performed to form front part 18 of the through-bore and narrow slot 20. Internal surfaces of the bore and slot are then coated with a protective material and an anisotropic wet etch is performed over the front surface, thereby forming the distinctive hollow microneedle structures of the '949 patent, for example, as illustrated in FIGS. 3A-3D. The protective material is then removed and, if the front and rear parts 18, 16 of the through-bore are not sufficiently deep to intersect, a final dry etch step may be performed from the backside of the wafer to complete the through-bore.

Turning now to FIGS. 3A-3D, these illustrate the primary defining features of the resulting microneedle structures according to certain preferred embodiments. Specifically, the external shape of the resulting microneedle 30 preferably includes a number of upright surfaces 22 (corresponding to an internal surface of slot 20 formed by the dry etching process of FIG. 2F) and at least one oblique surface 24 (formed by the wet etching process of FIG. 2G) which intersects the upright surfaces to define a cutting edge 26, and optionally also a point 28, of the microneedle. Front part 18 of the through-bore preferably intersects oblique surface 24 as shown. Rear part 16 of the through-bore may have a pyramidal form as illustrated in FIGS. 3A and 3B, formed by use of an anisotropic etching process at the etching stage of FIG. 2C, or may have a rounded form as illustrated in FIGS. 3C and 3D, formed by the use of an isotropic etching process at the etching stage of FIG. 2C.

As mentioned earlier, the order of the various front side and backside processing may be varied without departing from the general scope of the present invention. Certain particular choices of the order of various steps have accompanying advantages and disadvantages. For example, in the sequence as illustrated in FIGS. 2A-2G, the backside processing which forms rear part 16 of the through-bore is completed prior to the entire front side processing. This may simplify wafer handling, and allow the use of single-face wet etch equipment. In the front side etching procedure, on the other hand, the preferred microneedle structures according to the teachings of the '949 patent require performance of a dry etching process to form the upright surfaces prior to the wet etching process to form the oblique surface. Thus, the principle stages of the processing would be: backside wet etching; front side dry etching; front side wet etching.

In an alternative approach to the sequence of operations, it is possible to perform front side and backside wet etching processes concurrently, typically preceded by the front side dry etching required to form the upright surfaces of the microneedles and front part of the through-bore. This would reduce the number of process steps, and thus possibly also increase production rates.

The extent of the various wet etching processes may be limited to a required depth by various stopping techniques known in the field of MEMS and microelectronic production methods. By way of example, the processes may be stopped on the basis of elapsed time that the wafer is exposed to the chemical etching agent, or using in situ stopper such as embedded Boron atoms in concentration higher the 10¹⁹ per cubic centimeter (which are embedded by diffusion processes or by ion bombardment), or by any other conventional stopping mechanism, all as is known in the art.

In addition to the reduce fabrication time and cost achieved by the use of backside wet etching for part of the through-bore, the resulting structure is believed to provide one or more of a number of additional advantages. Specifically, by shortening the length of the narrow portion of the through-bore, fluid flow impedance is reduced. Furthermore, the shaped rear part of the through-bore serves as a tapered intake, reducing flow impedance for liquids (drugs or other materials) to be delivered to the skin, and rendering the liquid delivery more efficient, for example, allowing delivery of liquid at a given rate by a driving pressure lower than would otherwise be required. The use of reduced liquid pressure in turn reduces the mechanical stress exerted on the mounting of the microneedle array, e.g., adhesive, which holds the array in position.

In summary, it is believed that using wet etching processes to partially etch the silicon wafer back side of the microneedle/pyramid will provide one or more of the following advantages compared to a similar process performed exactly according to the teachings of the '949 patent:
1. reduce manufacturing costs;
2. reduce manufacturing time;
3. reduce flow impedance;
4. improve the delivery efficiency;
5. reduce the shear forces acting on molecules entering the backside hole;
6. reduce damage to molecules of drugs and other large-molecule compositions to be delivered through the needles;
7. facilitate monitoring and automatic stopping of DRIE by using back sensors sensitive to light or gases to sense full creation of through hole; and
8. allow a wider tolerance for DRIE etching of the front part of the liquid flow bore.

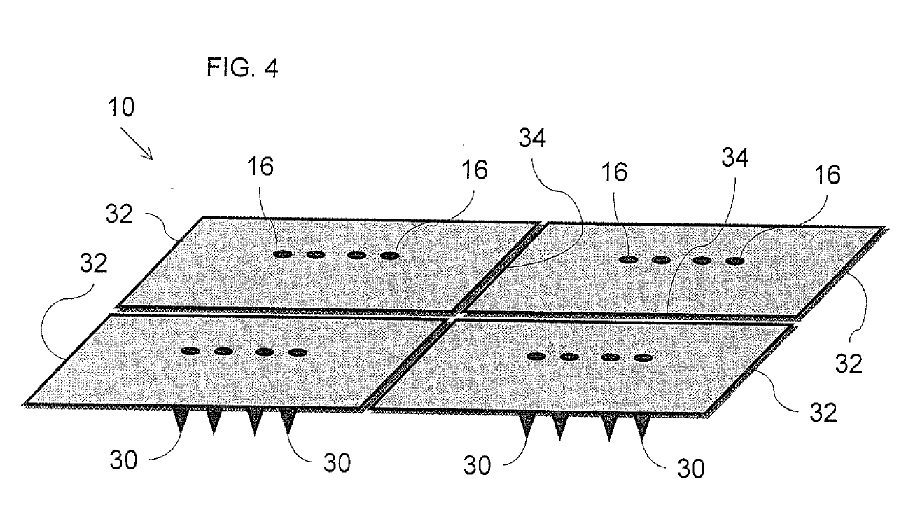

Turning now to the remaining FIGS. 4-6, there are illustrated certain additional aspects of the present invention which will be described below. It should be noted that these additional aspects of the present invention are considered to be of patentable significance, each in its own right, without dependence on the hybrid wet/dry etching implementation of the microneedle through-bores described above. Nevertheless, in certain particularly preferred implementations, each of these additional aspects, or combinations of these aspects, are used in synergy with the above-described microneedles structures and fabrication methods to particular advantage.

It should be noted that, although the schematic illustrations of FIGS. 2A-2G show a simplistic structure forming a single microneedle on a wafer, practical production is typically implemented by forming a plurality of microneedles 30 in distinct regions of wafer 10 which is subsequently subdivided along “dicing lines” into chips 32. Furthermore, each chip 32 typically carries a plurality of microneedles 30, which may be in a two dimensional array, or in certain particularly preferred implementations, a linear array. Thus, by way of non-limiting example FIGS. 4-6 will be illustrated in the context of one or more chips 32 carrying a linear array (row) of four microneedles 30, and thus having four corresponding through-bores with rear parts 16 reaching the wafer backside, as illustrated.

Referring specifically to FIG. 4, one of the processing operations which must be performed when fabricating a number of microneedle chips 32 from a single wafer is dicing in which the chips 32 are separated along dicing lines. According to a further aspect of the present invention, a wet etching process is used to form dicing channels 34 on at least one of the backside and the front side extending along dicing lines between the distinct regions. Advantageously, dicing channels 34, at least on the backside of the wafer, may be formed concurrently with the wet etching of the rear parts 16 of the through-bores described above. Dicing channels 34 may be formed on either the backside or the front side, and in certain cases preferably on both. In certain implementations, dicing channels 34 may be formed so as to traverse an entire thickness of the substrate, thereby completing the dicing operation without any mechanical cutting to separating the distinct regions into chips. Alternatively, the dicing channels may be formed so as to leave a remaining reduced thickness of the wafer along the dicing lines, followed by a mechanical dicing process to sever the remaining thickness of the wafer so as to separate the distinct regions into chips. Thus, the thermal and mechanical stress on the chip from the mechanical dicing process is either eliminated or greatly reduced.

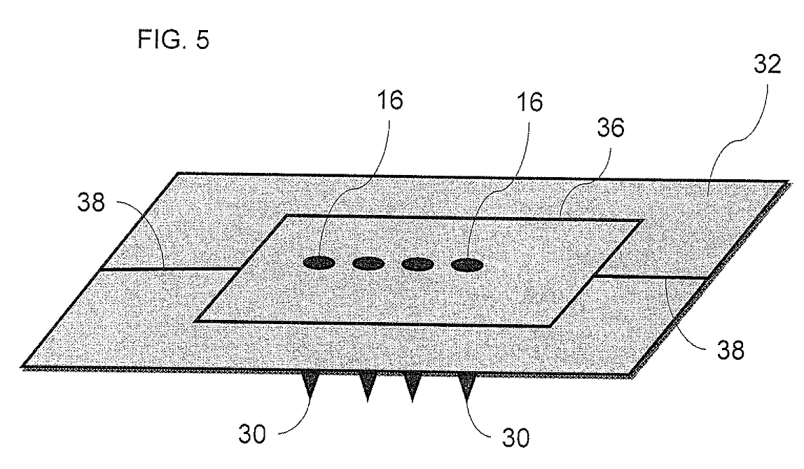

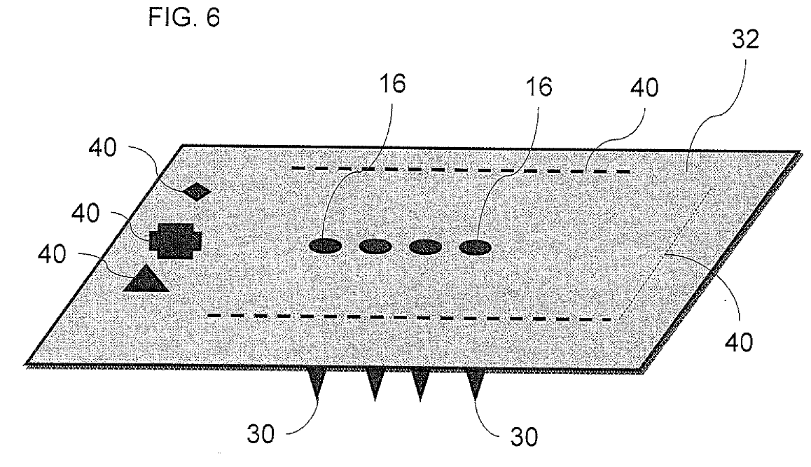

Turning now to FIGS. 5 and 6, there are illustrated two further aspects of the present invention particularly relevant to the primary mode of use of a microneedle chip 32, namely, for attachment to a support structure (not shown) to form a microneedle device. Such attachment is typically performed by use of adhesive to attach a peripheral region of the backside of chip 32 to the support structure. It is vital, however, that the adhesive does not spread to the region of the rear parts 16 of the through-bores where it would be likely to cause occlusion or otherwise interfere with operation of microneedles 30. For this purpose, certain particularly preferred implementations of the present invention include a trench 36 formed on the backside of chip 32 which substantially circumscribes rear parts 16 of the through-bore(s) of each chip and is spaced inwardly from the dicing lines (edges of the chip). Optionally, trench 36 may be supplemented by one or more trench extension 38 contiguous with trench 36 and extending to one of the dicing lines (edge of the chip). Trench extension 38 may operate as a drain for excess adhesive to avoid overspill of adhesive towards the region of the through-bores. Alternatively, particularly where there are two trench extensions 38 entering from different directions as shown, capillary action may be used to draw liquid adhesive along one trench extension 38 and into trench 36 as a technique for selective application of adhesive.

Parenthetically, it is noted that certain applications of the microneedle chips of the present invention have microneedles 30 located in close proximity to one edge of chip 32. In such cases, trench 36 is hereby defined to “substantially circumscribe” microneedles 30 if it extends around the microneedles on the remaining sides on which the microneedles are not in close proximity to the edge.

FIG. 6 illustrates a further aspect of the present invention according to which a plurality of non-contiguous recessed features 40 are formed on the backside so as to enhance an available contact surface for receiving an adhesive. The recessed features may take any desired form such as, for example, geometrical shapes, patterns, or broken lines, all as shown. Where this feature is combined with the trench feature of FIG. 5, the recesses are preferably formed outside the trench in the region intended for application of adhesive.

It will be noted that both the trench features of FIG. 5 and the recessed features of FIG. 6 may advantageously be formed by a wet etching process, and may be formed concurrently with formation of the rear part of the through-bore(s) as described above.

It will be appreciated that the above descriptions are intended only to serve as examples, and that many other embodiments are possible within the scope of the present invention as defined in the appended claims.

What is claimed is:

1. A method for forming a hollow microneedle structure comprising the steps of:
(a) providing a wafer having a front side and a backside;
(b) processing the front side to form at least one microneedle projecting from a substrate and a first part of a through-bore passing through said microneedle and through a part of a thickness of said substrate; and
(c) processing the backside to form a second part of said through-bore,
wherein said first part of said through-bore is formed by a dry etching process, and wherein said second part of said through-bore is formed by a wet etching process.

2. The method of claim 1, wherein said wafer is a silicon wafer.

3. The method of claim 1, wherein said second part of said through-bore is formed by an isotropic wet etching process.

4. The method of claim 1, wherein said second part of said through-bore is formed by an anisotropic wet etching process.

5. The method of claim 1, wherein said first part of said through-bore has an aspect ratio greater than 10:1.

6. The method of claim 1, wherein said first part of said through-bore is formed by deep reactive ion etching.

7. The method of claim 1, wherein an external shape of said microneedle is formed by at least two intersecting surfaces, at least a first of said surfaces being formed by a dry etching process and at least a second of said surfaces being formed by a wet etching process.

8. The method of claim 7, wherein said first surface and said first part of said through-bore are formed concurrently.

9. The method of claim 7, wherein said second surface and said second part of said through-bore are formed concurrently.

10. The method of claim 7, wherein said second part of said through-bore is formed prior to said first part of said through-bore, and wherein said second surface is formed subsequent to said first part of said through bore.

11. The method of claim 7, wherein said first part of said through-bore intersects said second surface.

12. The method of claim 1, further comprising processing said backside by a supplementary dry etch process to form a third part of said through-bore within said second part, said third part intersecting said first part to form said through-bore.

13. The method of claim 1, wherein a plurality of said microneedles with said through-bores are formed in distinct regions of said wafer for subdivision into chips, and wherein the method further comprises forming, by a wet etching process, dicing channels on at least one of said backside and said front side extending along dicing lines between said distinct regions.

14. The method of claim 13, wherein said dicing channels are formed concurrently with said second parts of said through-bores.

15. The method of claim 13, wherein said dicing channels are formed on both said front side and said backside.

16. The method of claim 13, wherein said dicing channels are formed so as to traverse an entire thickness of said substrate, thereby separating said distinct regions into chips.

17. The method of claim 13, further comprising performing a dicing process to sever a remaining thickness of said wafer after formation of said dicing channels so as to separate said distinct regions into chips.

18. The method of claim 1, wherein a plurality of said microneedles with said through-bores are formed in distinct regions of said wafer for subdivision along dicing lines into chips, and wherein the method further comprises forming, by a wet etching process, a trench on said backside, said trench substantially circumscribing said through-bore of each distinct region and spaced inwardly from said dicing lines.

19. The method of claim 18, further comprising forming on said backside by a wet etching process at least one trench extension contiguous with said trench and extending to one of said dicing lines.

20. The method of claim 18, further comprising forming on said backside outside said trench by a wet etching process a plurality of non-contiguous recessed features so as to enhance an available contact surface for receiving an adhesive.

21. The method of claim 18, further comprising:
(a) separating said distinct regions along said dicing lines so as to form chips;
(b) applying adhesive to a peripheral area of said backside of one of said chips outside said trench; and
(c) adhering said chip to a support structure to form a microneedle device,
such that any excess adhesive collects within said trench, thereby avoiding clogging of said through-bore.

22. The method of claim 1, wherein a plurality of said microneedles with said through-bores are formed in distinct regions of said wafer for subdivision along dicing lines into chips, and wherein the method further comprises forming, by a wet etching process, a plurality of non-contiguous recessed features on said backside so as to enhance an available contact surface for receiving an adhesive.

23. A hollow microneedle structure comprising:
(a) a substrate having a front side and a backside;
(b) at least one microneedle projecting from said front side of said substrate; and
(c) a through-bore passing through said microneedle and through said substrate,
wherein a first part of said through-bore extending from said microneedle through a first portion of a thickness of said substrate is formed by a dry etching process, and wherein a second part of said through-bore extending from said backside through a second portion of said thickness of said substrate is formed by a wet etching process.

24. The structure of claim 23, wherein said substrate and said microneedle are formed from silicon.

25. The structure of claim 23, wherein said second part of said through-bore is formed by an isotropic wet etching process.

26. The structure of claim 23, wherein said second part of said through-bore is formed by an anisotropic wet etching process.

27. The structure of claim 23, wherein said first part of said through-bore has an aspect ratio greater than 10:1.

28. The structure of claim 23, wherein an external shape of said microneedle is formed by at least two intersecting surfaces, at least a first of said surfaces being an upright surface relative to said front side and at least a second of said surfaces being an oblique surface relative to said front side.

29. The structure of claim 28, wherein said first part of said through-bore intersects said oblique surface.

30. The structure of claim 23, wherein said substrate has a boundary, and wherein said backside features a trench substantially circumscribing said through-bore and spaced inwardly from said boundary.

31. The structure of claim 30, wherein said backside further includes at least one trench extension formed by a wet etching process, said trench extension being contiguous with said trench and extending said boundary.

32. The structure of claim 30, further comprising:
(a) a support structure for supporting said substrate; and
(b) a layer of adhesive applied to a peripheral area of said backside outside said trench, said layer of adhesive attaching said substrate to said support structure.

33. The structure of claim 23, wherein said backside further includes a plurality of non-contiguous recessed features formed by a wet etching process so as to enhance an available contact surface for receiving an adhesive.

34. A method for forming a hollow microneedle structure comprising the steps of:
(a) providing a wafer having a front side and a backside;
(b) processing the front side to form:
(i) a plurality of microneedles projecting from a substrate in distinct regions of said wafer for subdivision along dicing lines into chips, and
(ii) a first part of a through-bore passing through each of said microneedles and through a part of a thickness of said substrate; and
(c) processing the backside to form:
(i) a second part of said through-bore for each microneedle, and
(ii) a trench substantially circumscribing said through-bore of each distinct region and spaced inwardly from said dicing lines.

35. A method for forming a hollow microneedle structure comprising the steps of:
(a) providing a wafer having a front side and a backside;
(b) processing the front side to form:
(i) a plurality of microneedles projecting from a substrate in distinct regions of said wafer for subdivision along dicing lines into chips, and
(ii) a first part of a through-bore passing through each of said microneedles and through a part of a thickness of said substrate; and
(c) processing the backside to form:
(i) a second part of said through-bore for each microneedle, and
(ii) a plurality of non-contiguous recessed features so as to enhance an available contact surface for receiving an adhesive.

36. A method for forming a hollow microneedle structure comprising the steps of:
(a) providing a wafer having a front side and a backside;
(b) processing the front side to form:
(i) a plurality of microneedles projecting from a substrate in distinct regions of said wafer for subdivision along dicing lines into chips, and
(ii) at least part of a through-bore passing through each of said microneedles and a thickness of said substrate; and
(c) forming, by a wet etching process, dicing channels on at least one of said backside and said front side extending along dicing lines between said distinct regions.
